(19) United States
(12) Patent Application Publication
(10) Pub. No.: US 2019/0172889 A1
(43) Pub. Date: Jun. 6, 2019

(54) WIRING STRUCTURE AND DISPLAY DEVICE HAVING THE WIRING STRUCTURE

(71) Applicant: JAPAN DISPLAY INC., Tokyo (JP)

(72) Inventor: Kenta KAJIYAMA, Tokyo (JP)

(21) Appl. No.: 16/183,039

(22) Filed: Nov. 7, 2018

(30) Foreign Application Priority Data
Dec. 4, 2017 (JP) 2017-232542

(51) Int. Cl. H01L 27/32; H01L 51/52; G09G 3/3233

(52) U.S. Cl. CPC H01L 27/3276; G09G 3/3233; H01L 51/5203

(57) ABSTRACT

Provided is a wiring structure having: a first wiring; a first insulating film over the first wiring; a second wiring over the first insulating film, the second wiring intersecting the first wiring; an electrode over the first insulating film, the electrode being spaced from the second wiring; and a second insulating film over the second wiring and the electrode. The entire electrode overlaps with the first wiring. A top surface of the first insulating film is entirely in contact with the second insulating film over the first wiring and between the second wiring and the electrode.

### CROSS REFERENCE TO RELATED APPLICATIONS

This application is based on and claims the benefit of priority from the prior Japanese Patent Application No. 2017-232542, filed on Dec. 4, 2017, the entire contents of which are incorporated herein by reference.

### FIELD

An embodiment of the present invention relates to a wiring structure in which a plurality of wirings is arranged and a semiconductor device such as a display device having the wiring structure.

### BACKGROUND

A semiconductor device is a stacked body of a variety of conductive films, semiconductor films, and insulating films provided over a substrate such as a semiconductor substrate and a glass substrate, and appropriate patterning and arrangement of these films make it possible to realize a variety of functions as a semiconductor device. An example of a semiconductor device is a display device exemplified by a liquid crystal display device and an organic EL (Electroluminescence) display device. In a manufacturing process of a display device, a variety of conductive layers, semiconductor layers, and insulating layers is deposited over a large glass substrate and subjected to patterning, thereby forming elements such as a transistor, a capacitor element, and a display element as well as wiring electrically connecting the elements.

High integration of a semiconductor device and an increase in resolution of a display device have required highly dense arrangement of elements and wirings over a substrate. Hence, a patterning defect leaving a conductive residue on a substrate readily induces a short circuit between closely disposed wirings. Thus, a variety of structures to prevent a short circuit between wirings is proposed in Japanese Patent Application Publications No. H8-46148, H10-253989, and 2000-260868.

### SUMMARY

An embodiment of the present invention is a wiring structure. The wiring structure possesses: a first wiring; a first insulating film over the first wiring; a second wiring over the first insulating film and intersecting the first wiring; an electrode over the first insulating film and spaced from the second wiring; and a second insulating film over the second wiring and the electrode. The entire electrode overlaps with the first wiring. A top surface of the first insulating film is entirely in contact with the second insulating film over the first wiring and between the second wiring and the electrode.

An embodiment of the present invention is a display device. The display device possesses a transistor, a leveling film over the transistor, a display element over the leveling film, and a first wiring. The transistor includes a semiconductor film, a gate insulating film over the semiconductor film, a gate over the gate insulating film, a first interlayer insulating film over the gate, a second interlayer insulating film over the first interlayer insulating film, a first terminal over the second interlayer insulating film, and a second terminal over the second interlayer insulating film. The display element is electrically connected to the second terminal. The first wiring is sandwiched between the first interlayer insulating film and the second interlayer insulating film and electrically connected to the first terminal. The first wiring has an opening, and the second interlayer insulating film is in contact with the leveling film and the first interlayer insulating film through the opening.

An embodiment of the present invention is a display device. The display device possesses a transistor, a display element, and a first wiring. The transistor includes a semiconductor film, a gate insulating film over the semiconductor film, a gate over the gate insulating film, a first interlayer insulating film over the gate, a second interlayer insulating film over the first interlayer insulating film, a first terminal over the second interlayer insulating film, and a second terminal over the second interlayer insulating film. The display element is electrically connected to the second terminal. The first wiring is sandwiched between the first interlayer insulating film and the second interlayer insulating film and electrically connected to the first terminal. The entire first terminal is surrounded by an outline of the first wiring.

### BRIEF DESCRIPTION OF DRAWINGS

FIG. 1A is a schematic top view, and FIG. 1B to FIG. 1D are schematic cross-sectional views of a wiring structure according to an embodiment of the present invention;

FIG. 2A to FIG. 2C are schematic cross-sectional views of a wiring structure according to an embodiment of the present invention;

FIG. 3A and FIG. 3B are schematic cross-sectional views of a wiring structure according to an embodiment of the present invention;

FIG. 4A is a top view, and FIG. 4B and FIG. 4C are cross-sectional views schematically showing a part of a conventional wiring structure;

FIG. 5A is a top view, and FIG. 5B and FIG. 5C are cross-sectional views schematically showing a part of a wiring structure according to an embodiment of the present invention;

FIG. 6A is a schematic top view and FIG. 6B and FIG. 6C are schematic cross-sectional views of a wiring structure according to an embodiment of the present invention;

FIG. 7A is a schematic top view and FIG. 7B and FIG. 7C are schematic cross-sectional views of a wiring structure according to an embodiment of the present invention;

FIG. 8A is a schematic top view and FIG. 8B and FIG. 8C are schematic cross-sectional views of a wiring structure according to an embodiment of the present invention;

FIG. 9 is a schematic top view of a display device according to an embodiment of the present invention;

FIG. 10 is an equivalent circuit of a pixel of a display device according to an embodiment of the present invention;

FIG. 11 is a schematic top view of a pixel of a display device according to an embodiment of the present invention;

FIG. 12 is a schematic cross-sectional view of a pixel of a display device according to an embodiment of the present invention;

FIG. 13A and FIG. 13B are respectively a schematic top view and cross-sectional view of a pixel of a display device according to an embodiment of the present invention;

FIG. 14 is a schematic cross-sectional view of a pixel of a display device according to an embodiment of the present invention;

FIG. 15 is a schematic top view of a pixel of a display device according to an embodiment of the present invention; and

FIG. 16 is a schematic cross-sectional view of a pixel of a display device according to an embodiment of the present invention.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

When a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer in the specification.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the scope of the claims, an expression that “a structural member is exposed from another structural member” means a mode where a part of the structural member is not covered by the other structural member and included a mode where the portion of the structural member which is not covered by the other structural member is further covered by another structural member.

### First Embodiment

### 1. Structure

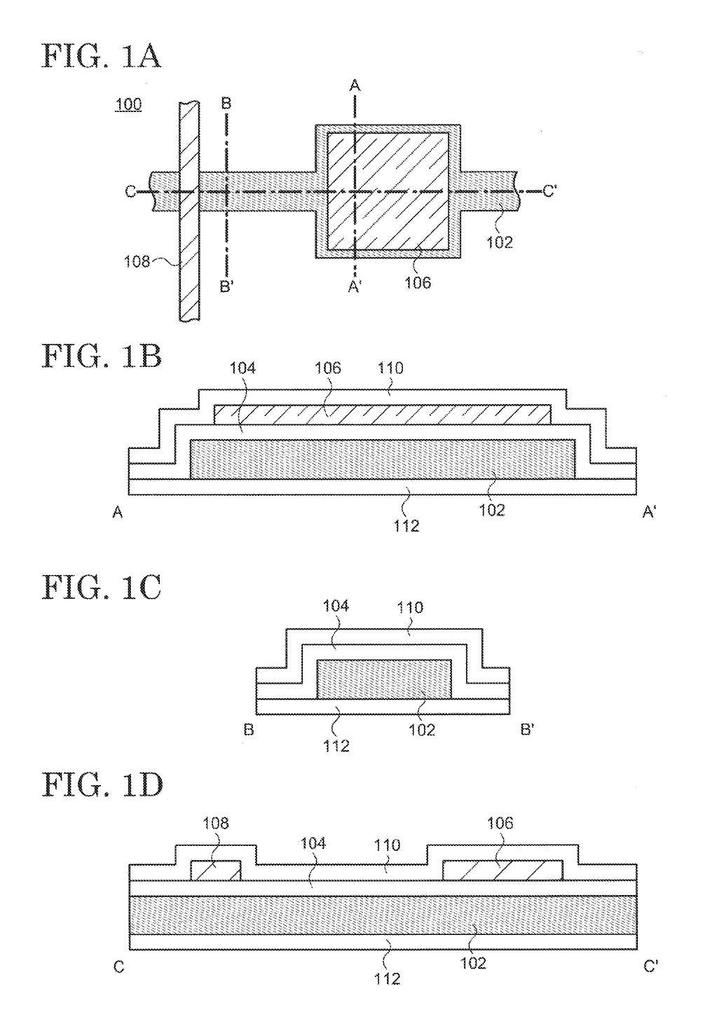

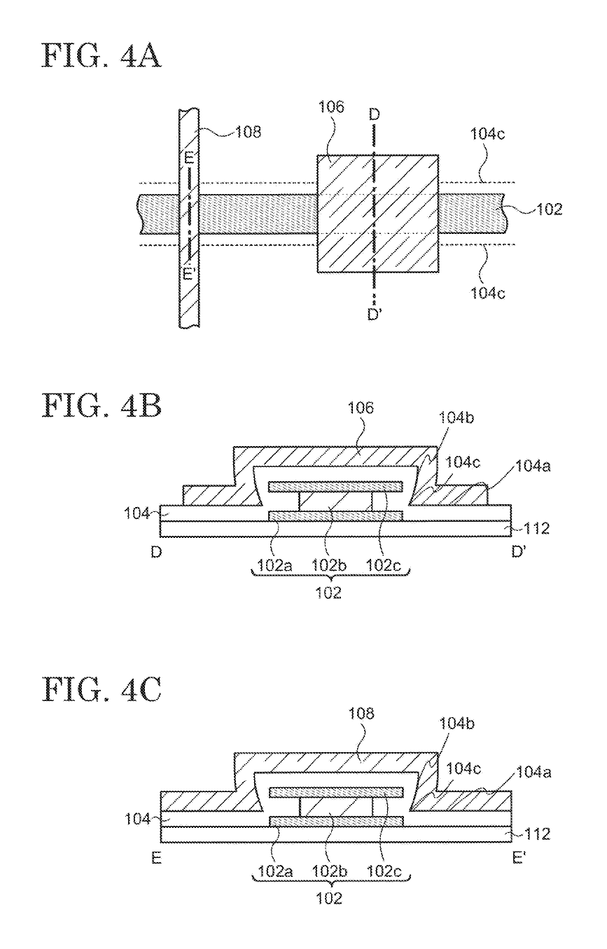

A schematic top view of a wiring structure 100 according to an embodiment of the present invention is shown in FIG. 4A, and schematic views of cross sections along chain lines A-A′, B-B′, and C-C′ are respectively illustrated in FIG. 1B to FIG. 1D. As shown in these drawings, the wiring structure 100 possesses a first wiring 102, a first insulating film 104 located over and overlapping with the first wiring 102, an electrode 106 and a second wiring 108 over the first insulating film 104, and a second insulating film 110 located over and overlapping with the electrode 106 and the second wiring 108. The second wiring 108 and the electrode 106 are spaced apart from each other and exist in the same layer. That is, the second wiring 108 and the electrode 106 are formed in the same process and are able to have the same composition. The electrode 106 is formed in an island shape and overlaps with the first wiring 102. More specifically, the entire electrode 106 is surrounded by an outline of the first wiring 102 when viewed from above. In other words, the entire bottom surface of the electrode 106 overlaps with the first wiring 102. The second wiring 108 intersects the first wiring 102. An intersecting angle between the first wiring 102 and the second wiring 108 is arbitrary and the second wiring 108 and the first wiring 102 may perpendicularly intersect each other. For example, this angle is equal to or more than 30° and equal to or less than 90°, equal to or more than 45° and equal to or less than 90°, or equal to or more than 60° and equal to or less than 90°. As an optional structure, the wiring structure 100 may have a third insulating film 112 under the first wiring 102. The wiring structure 100 may be configured so that the second wiring 108 and the electrode 106 are applied with potentials different from each other.

Although not illustrated, a wiring and an electrode existing in the same layer as the second wiring 108 and the electrode 106 may be provided between the second wiring 108 and the electrode 106. Alternatively, no wiring and electrode existing in the same layer as the second wiring 108 and the electrode 106 may be provided between the second wiring 108 and the electrode 106 as shown in FIG. 1A. In the latter case, a top surface of the first insulating film 104 is entirely in contact with the second insulating film 110 over the first wiring 102 and between the second wiring 108 and the electrode 106.

The first insulating film 104, the second insulating film 110, and the third insulating film 112 are each an insulating film containing an inorganic compound, and a silicon-containing inorganic compound is represented as an inorganic compound. As a silicon-containing inorganic compound, silicon oxide, silicon nitride, silicon oxynitride, and silicon nitride oxide are exemplified. These films may have a single-layer structure or a structure in which a plurality of layers including different materials is stacked.

The first wiring 102, the second wiring 108, and the electrode 106 include a metal (0-valent metal) or an alloy thereof, and the metal is selected from titanium, molybdenum, tungsten, tantalum, chromium, aluminum, copper, and the like, for example.

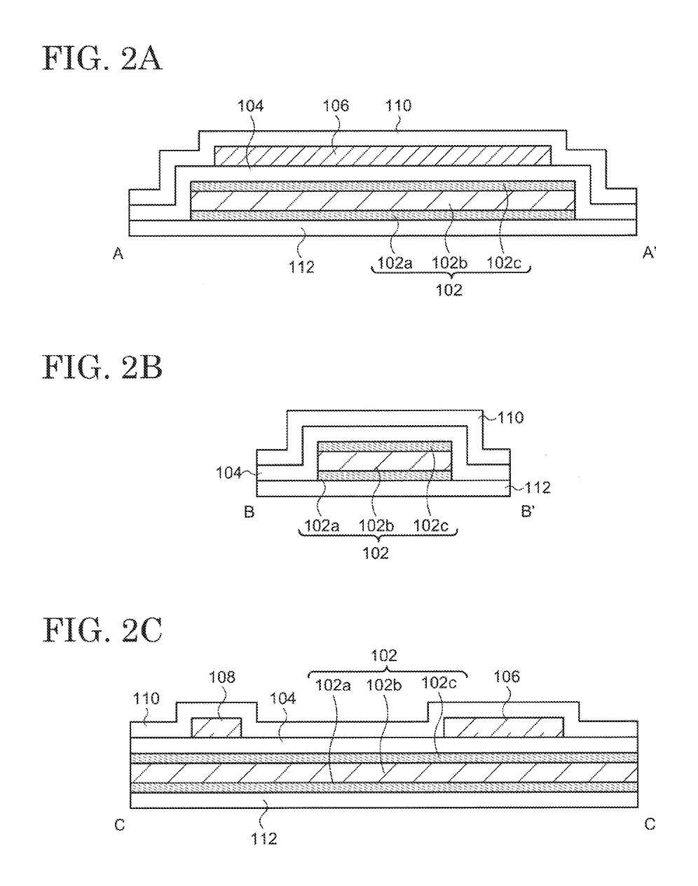

The first wiring 102, the second wiring 108, and the electrode 106 may have a single-layer structure as shown in FIG. 1A or may be composed of a plurality of layers. For example, the first wiring 102 may have a three-layer structure in which a first conductive film 102a, a second conductive film 102b, and a third conductive film 102c are stacked as shown in FIG. 2A to FIG. 2C. In this case, the first wiring 102 may be configured so that the second conductive film 102b includes a highly conductive metal such as aluminum and copper and the first conductive film 102a and the third conductive film 102c include a metal with a high melting point, such as titanium, molybdenum, tungsten, or an alloy thereof. As a typical example of the three-layer structure, titanium/aluminum/titanium, molybdenum-tungsten alloy/aluminum/molybdenum-tungsten alloy, and the like are represented. Although not illustrated, the electrode 106 and the second wiring 108 may also have the same structure.

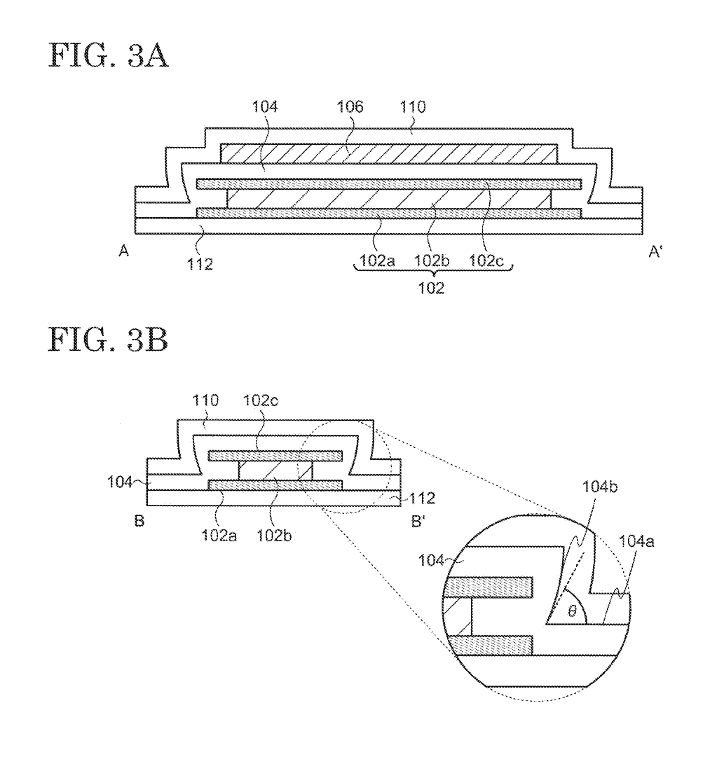

When the first wiring 102, the second wiring 108, or the electrode 106 possesses the three-layer structure, side surfaces of the first conductive film 102a, the second conductive film 102b, and the third conductive film 102c may not exist in the same plane. For example, the first wiring 102, the second wiring 108, and the electrode 106 may be configured so that a side surface of the second conductive film 102b overlaps with at least one of a top surface of the first conductive film 102a and a bottom surface of the third conductive film 102c as shown in FIG. 3A and FIG. 3B. Since the first insulating film 104 covers the first wiring 102, a step is produced in the first insulating film 104 due to the first wiring 102. When the first wiring 102 has the aforementioned structure, a side surface 104b in the step of the first insulating film 104 is included so that a lower portion thereof is closer to the first wiring 102 than is the upper portion as shown in FIG. 3A and FIG. 3B. As a result, a constriction is formed in a part of the first insulating film 104 to give a reverse-taper structure to the first insulating film 104. That is, an angle e between the top surface 104a of the first insulating film 104, which does not overlap with the first wiring 102, and the side surface 104b is not 90° but equal to or more than 0° and less than 90° in a cross section (FIG. 3B). Note that, when the side surface 104b is a curved surface, this angle θ is defined as an angle between the top surface 104a and a tangent of the side surface 104b passing through a cross point of the top surface 104a with the side surface 104b in a cross section.

FIG. 4A shows a top view explaining a problem of a conventional wiring structure, and cross-sectional views along chain lines D-D′ and E-E′ are respectively illustrated in FIG. 4B and FIG. 4C. In these drawings, the second insulating film 110 is omitted. In this conventional structure, a part of the electrode 106 overlaps with the first wiring 102, while another part does not overlap with the first wiring 102.

The second wiring 108 and the electrode 106 are prepared by forming a metal film over the first insulating film 104 by utilizing a sputtering method or a chemical vapor deposition (CVD) method and patterning the metal film with etching. At this time, an etching residue with conductivity, which originates from the metal film and which is not completely removed in the etching or a washing process after the etching, may be left. This residue tends to remain at the step, that is, at a boundary 104c between the top surface 104a and the side surface 104b and a vicinity thereof. Particularly, there is a high probability of the etching residue remaining when the first insulating film 104 has a reverse-taper structure. Since this boundary 104c extends along the first wiring 102 so as to sandwich the first wiring 102 as indicated by a dotted line in FIG. 4A, the second wiring 108 and the electrode 106 overlap with this boundary 104c. Hence, the etching residue conducts the second wiring 108 with the electrode 106 and causes a short circuit therebetween. In particular, there is a high probability of a short circuit being induced when a distance between the second wiring 108 and the electrode 106 is small.

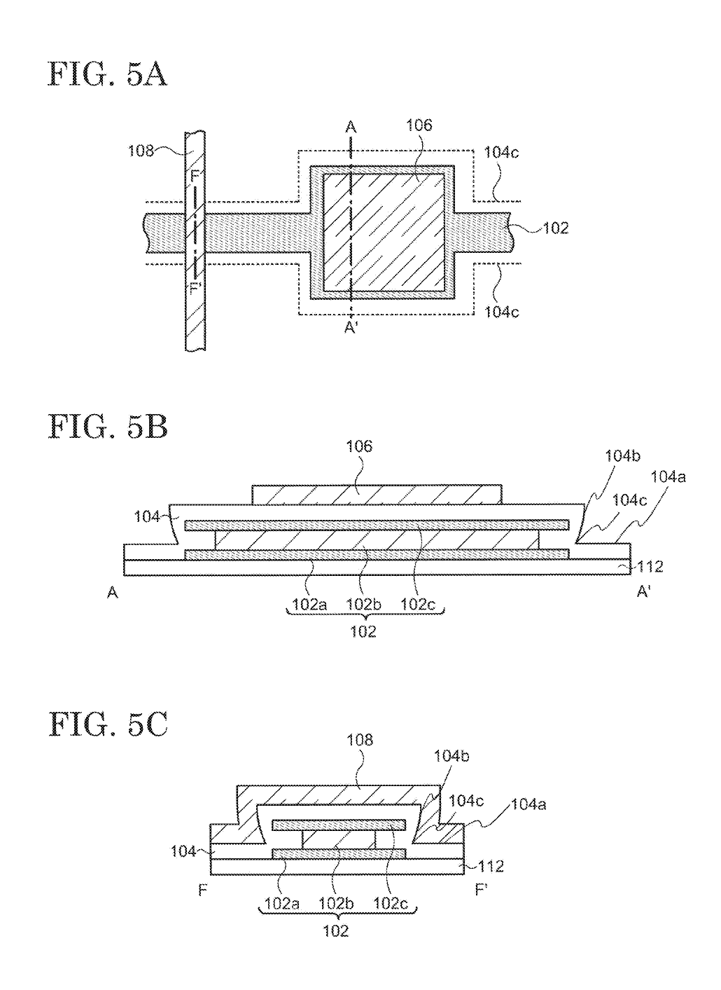

In contrast, the entire bottom surface of the electrode 106 overlaps with the first wiring 102 in the wiring structure 100 as described above. Thus, although the second wiring 108 overlaps with the boundary 104c in the wiring structure 100, the electrode 106 does not overlap with and is not in contact with the boundary 104c as demonstrated in the top view of FIG. 5A and the schematic cross-sectional views along the chain lines A-A′ and F-F′ (FIG. 5B, FIG. 5C). Therefore, application of the wiring structure 100 effectively prevents a short circuit between the second wiring 108 and the electrode 106, by which a highly reliable wiring structure as well as a circuit structure including the wiring structure can be provided.

### 2. Modified Example 1

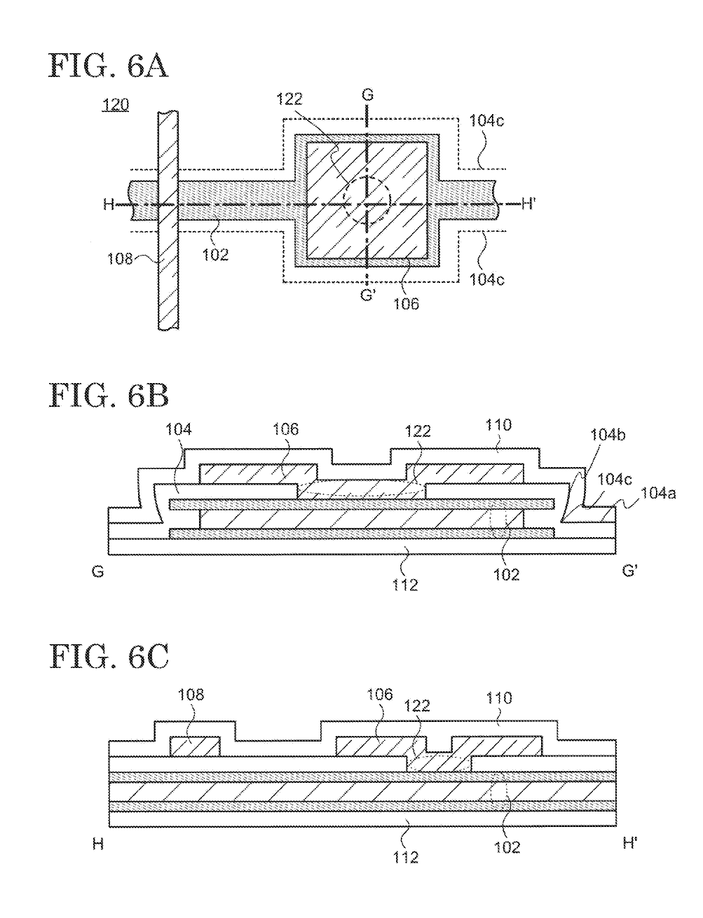

A schematic top view of a wiring structure 120 according to the present embodiment, which is different in structure from the wiring structure 100, is shown in FIG. 6A. FIG. 6B and FIG. 6C are schematic cross-sectional views along chain lines G-G′ and H-H′ in FIG. 6A, respectively. The wiring structure 120 is different from the wiring structure 100 shown in FIG. 3A in that the first insulating film 104 possesses an opening 122 overlapping with the first wiring 102 and that the first wiring 102 and the electrode 106 are electrically connected to each other through this opening 122.

Similar to the wiring structure 100, the boundary 104c does not overlap with the electrode 106 in the wiring structure 120 because the entire bottom surface of the electrode 106 overlaps with the first wiring 102 and the electrode 106 is entirely surrounded by the outline of the first wiring 102 in a plane view. Hence, it is possible to effectively prevent a short circuit between the second wiring 108 and the electrode 106 and between the second wiring 108 and the first wiring 102.

### 3. Modified Example 2

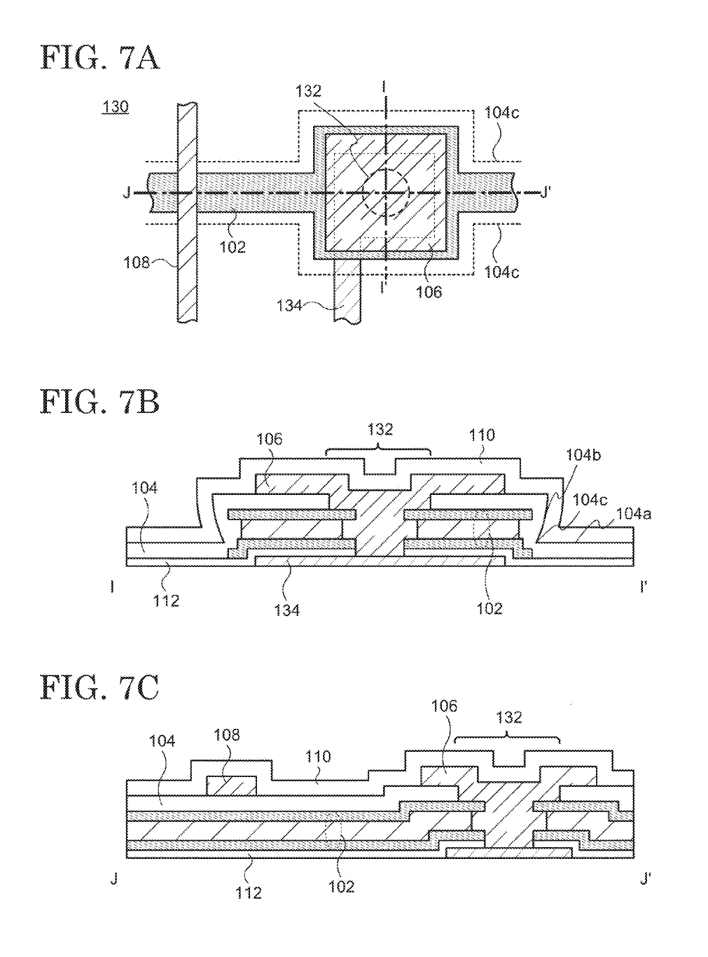

A schematic top view of a wiring structure 130 according to the present embodiment, which is different in structure from the wiring structures 100 and 120, is shown in FIG. 7A. FIG. 7B and FIG. 7C are schematic cross-sectional views along chain lines I-I′ and J-J′ of FIG. 7A, respectively. The wiring structure 130 is different from the wiring structures 100 and 120 in that the wiring structure 130 possesses, under the first wiring 102, a third wiring 134 overlapping with the first wiring 102 and the electrode 106 through the third insulating film 112, that the first wiring 102, the third insulating film 112, and the first insulating film 104 are each provided with an opening (hereinafter, these openings are collectively referred to as an opening 132), and that the electrode 106 is electrically connected to the first wiring 102 and the third wiring 134 through this opening 132.

Similar to the first wiring 102, the second wiring 108, and the electrode 106, the third wiring 134 may include a 0-valent metal, a Group 14 element such as silicon and germanium, or an oxide semiconductor. As an oxide semiconductor, an indium-zinc mixed oxide (IZO), an indium-gallium-zinc mixed oxide (IGZO), and the like are represented. The third wiring 134 may be doped with an impurity. As an impurity, ions of boron, aluminum, nitrogen, and phosphorus are exemplified. A conductivity of the third wiring 134 may be the same as or lower than those of the first wiring 102, the second wiring 108, and the electrode 106. For example, a part of the third wiring 134 may exhibit a property as a semiconductor. Crystallinity of the third wiring 134 is not limited and may be single crystalline, polycrystalline, microcrystalline, or amorphous.

The openings respectively formed in the first wiring 102, the third insulating film 112, and the first insulating film 104 may be different in size and shape from one another. For example, the opening may be formed in the first insulating film 104 so as to include the entire opening formed in the first wiring 102 when viewed from above. Alternatively, the opening of the third insulating film 112 and the opening of the first wiring 102 may be the same in size and shape. In this case, a sidewall of the opening of the third insulating film 112 may exist in the same plane as a sidewall of the first conductive film 102a or the third conductive film 102c as illustrated in FIG. 7B and FIG. 7C.

Similar to the wiring structures 100 and 120, the boundary 104c does not overlap with the electrode 106 in the wiring structure 130 because the entire bottom surface of the electrode 106 overlaps with the first wiring 102 and the electrode 106 is entirely surrounded by the outline of the first wiring 102 when viewed from above. Therefore, it is possible to effectively prevent a short circuit between the second wiring 108 and the electrode 106, between the second wiring 108 and the first wiring 102, and between the second wiring 108 and the third wiring 134.

### 4. Modified Example 3

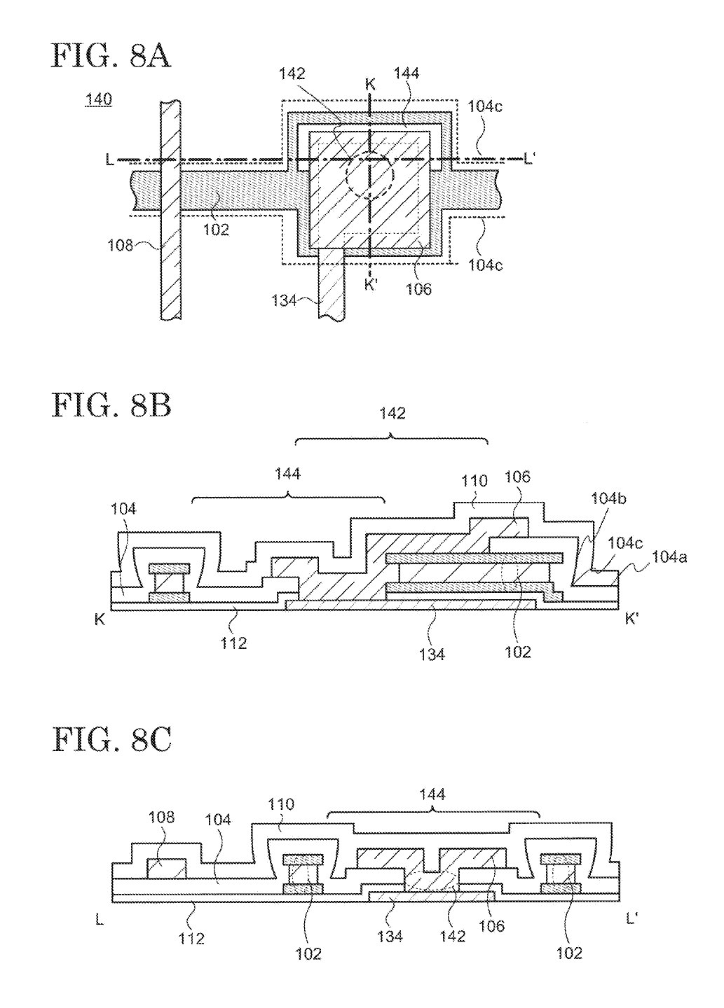

A schematic top view of a wiring structure 140 according to the present embodiment, which is different in structure from the wiring structures 100, 120, and 130 is shown in FIG. 8A. FIG. 8B and FIG. 8C are schematic cross-sectional views along chain lines K-K′ and L-L′ in FIG. 8A, respectively. The wiring structure 140 is different from the wiring structure 130 in that the third insulating film 112 and the first insulating film 104 are each provided with an opening (hereinafter, these openings are collectively referred to as an opening 142), that an opening 144 partly overlapping with the opening 142 is formed in the first wiring 102, and that the first insulating film 104 is in contact with the second insulating film 110 and the third insulating film 112 in this opening 144. The openings 142 and 144 partly overlap with each other through which the electrode 106 is electrically connected to the first wiring 102 and the third wiring 134.

As described above, the first wiring 102 possesses the opening 144 in which the first insulating film 104 is in contact with the second insulating film 110 and the third insulating film 112. Therefore, the first wiring 102 surrounds a part of the electrode 106 and has a bypass structure spaced apart from the electrode 106 when viewed from above (FIG. 8A). This bypass structure forms the opening 144. Similar to the wiring structure 130, the boundary 104c does not overlap with the electrode 106 because the boundary 104c is formed along this bypass structure. Hence, it is possible to effectively prevent a short circuit between the second wiring 108 and the electrode 106, between the second wiring 108 and the first wiring 102, and between the second wiring 108 and the third wiring 134.

### Second Embodiment

In the present embodiment, an explanation is given for a structure of a display device 200 as an example of a semiconductor device in which a plurality of pixels having the wiring structure 140 described in the First Embodiment is arranged. In the present embodiment, the display device 200 having a light-emitting element as a display device is explained. An explanation the same as or similar to that of the First Embodiment may be omitted.

### 1. Outline Structure

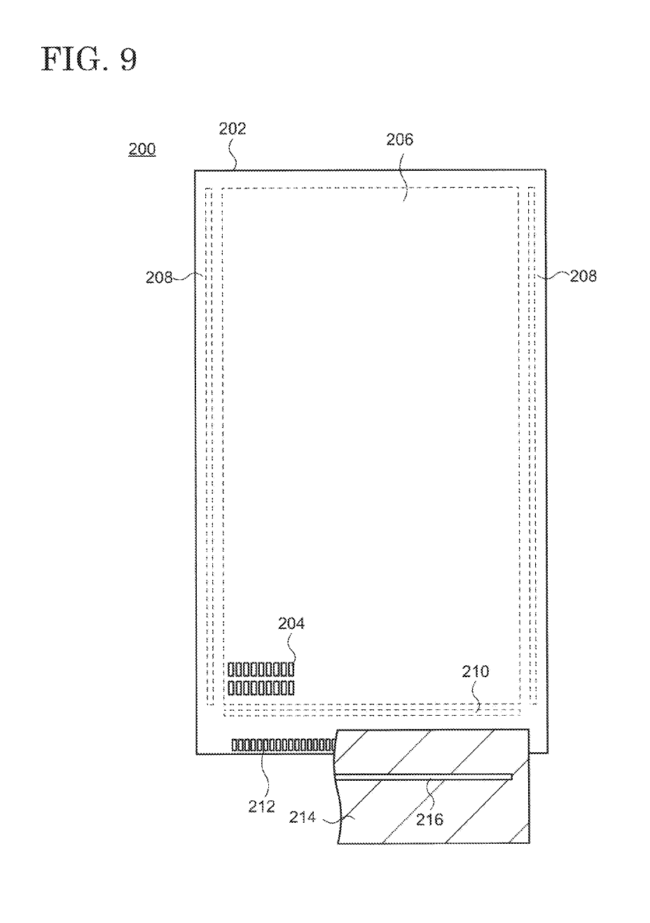

A schematic top view of the display device 200 is illustrated in FIG. 9. The display device 200 has a substrate 202 and possesses a variety of patterned insulating films, semiconductor films, and conductive films thereover. A plurality of pixels 204 and driver circuits (gate-side driver circuits 208 and a source-side driver circuit 210) for driving the pixels 204 are fabricated with these insulating films, semiconductor films, and conductive films. The plurality of pixels 204 is periodically arranged, by which a display region 206 is defined. As described below, the wiring structure 140 as well as a light-emitting element 262 is disposed in each pixel 204.

The gate-side driver circuits 208 and the source-side driver circuit 210 are arranged outside the display region 206 (periphery region). A variety of wirings (not illustrated) formed with the patterned conductive films extends from the display region 206, the gate-side driver circuits 208, and the source-side driver circuit 210 to a side of the substrate 202 and is exposed at a vicinity of an edge portion of the substrate 202 to form terminals 212. These terminals 212 are electrically connected to a flexible printed circuit substrate (FPC) 214. In the example shown here, a driver IC 216 including an integrated circuit formed over a semiconductor substrate is further mounted over the FPC 214. Image signals are supplied from an external circuit (not illustrated) to the gate-side driver circuits 208 and the source-side driver circuit 210 through the driver IC 216, the FPC 214, and the terminals 212. Signals based on the image signals are provided to each pixel 204 to control and drive the pixels 204. A configuration of the driver circuits and the driver IC 216 is not limited to that shown in FIG. 9: the driver IC 216 may be mounted over the substrate 202, and a function of the source-side driver circuit 210 may be integrated with the driver IC 216, for example.

### 2. Pixel Circuit

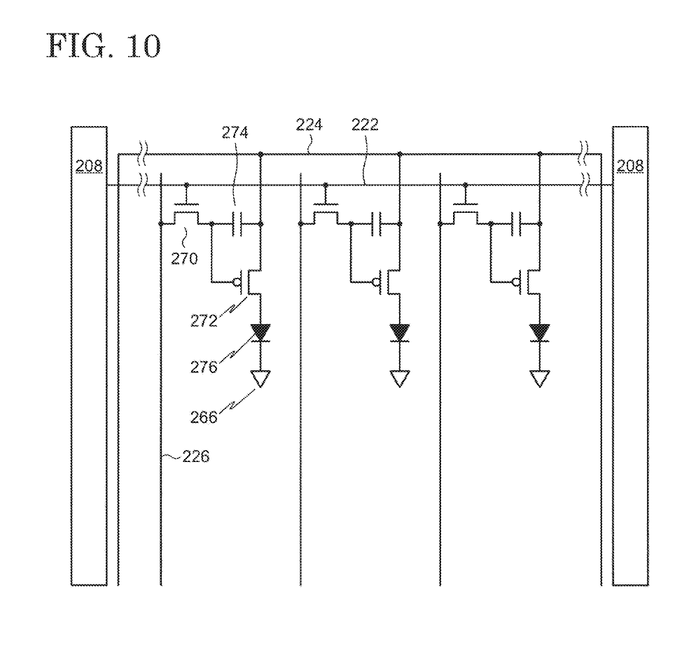

Equivalent circuits of the pixel 204 are shown in FIG. 10. Here, equivalent circuits of three adjacent pixels 204 are illustrated. Each pixel 204 has a pixel circuit electrically connected to a gate line 222 extending from the gate-side driver circuit 208 and a signal line 226 extending from the driver IC 216 through the terminal 212. In the example shown here, the pixel circuit possesses two transistors (a switching transistor 270 and a driving transistor 272), one storage capacitor 274, and one light-emitting element 262. A gate of the switching transistor 270 is electrically connected to the gate line 222, while one terminal (source) is connected to the signal line 226. The other terminal (drain) of the switching transistor 270 is electrically connected to one electrode of the storage capacitor 274 and a gate of the driving transistor 272. A current-supplying line 224 is electrically connected to the other terminal of the storage capacitor 274 and one terminal (source) of the driving transistor 272, while the other terminal (drain) of the driving transistor 272 is electrically connected to one electrode (pixel electrode) of the light-emitting element 262.

The image signals supplied from the signal line 226 are provided to the gate of the driving transistor 272 through the switching transistor 270, by which a potential of the gate of the driving transistor 272 is controlled. The storage capacitor 274 is disposed to maintain this potential of the gate. On/off of the driving transistor 272 is determined by the potential of the gate of the driving transistor 272: when the driving transistor 272 is on, current supplied through the current-supplying line 224 is provided to the light-emitting element 262, thereby giving light emission. Note that the structure of the pixel circuit is not limited to this structure, and the number of transistors and storage capacitors and the connection thereof are not limited. For example, the pixel circuit may be configured to compensate a threshold voltage of the driving transistor 272 by further adding a transistor and a storage capacitor.

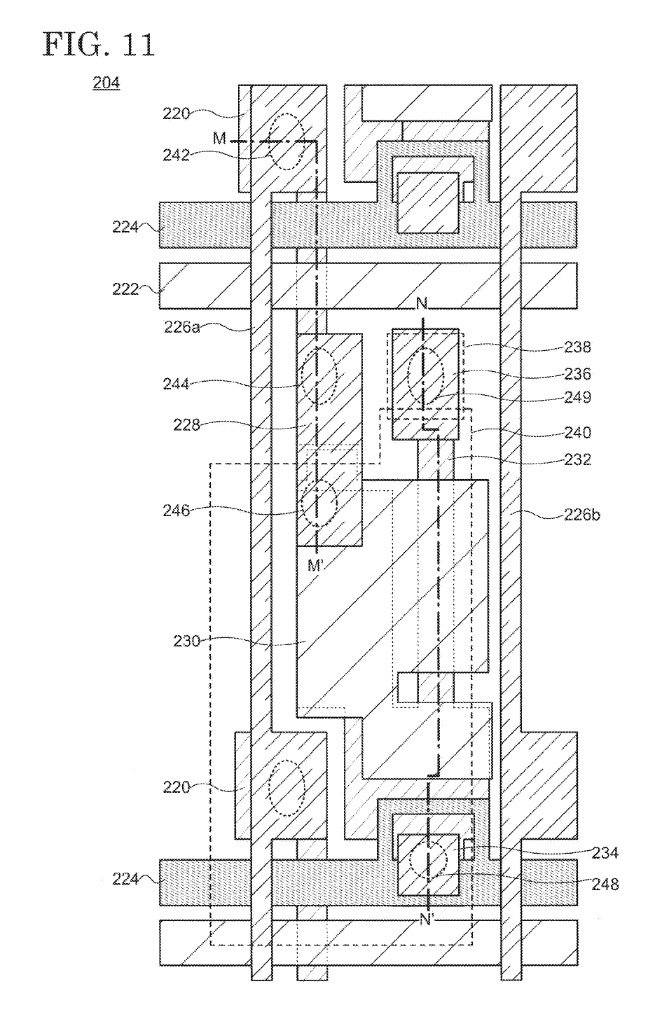

A schematic top view of one pixel 204 is shown in FIG. 11. As shown in FIG. 11, each pixel 204 possesses, as main structures, semiconductor films 220 and 232, the gate line 222, a gate electrode 230, the current-supplying line 224, the signal line 226a, a source electrode 234, drain electrodes 228 and 236, a connection electrode 238, and the pixel electrode 240, and the like. One pixel 204 and a part of the adjacent pixel 204 are illustrated in FIG. 11, and the signal line 226a on the left side among two signal lines 226 supplies the image signals to the pixel 204 shown in FIG. 11. On the other hand, the signal line 226b on the right side supplies the image signals to the adjacent pixel 204. Note that, with respect to the structure of the adjacent pixel 204, only the signal line 226b is illustrated for visibility. The plurality of current-supplying lines 224 extending parallel to the gate line 222 is electrically connected to each other with a wiring extending in a direction in which the signal lines 226 extend (see FIG. 10). Hereinafter, the structure of the pixel 204 is explained by using cross-sectional views along dashed lines M-M′ and N-N′.

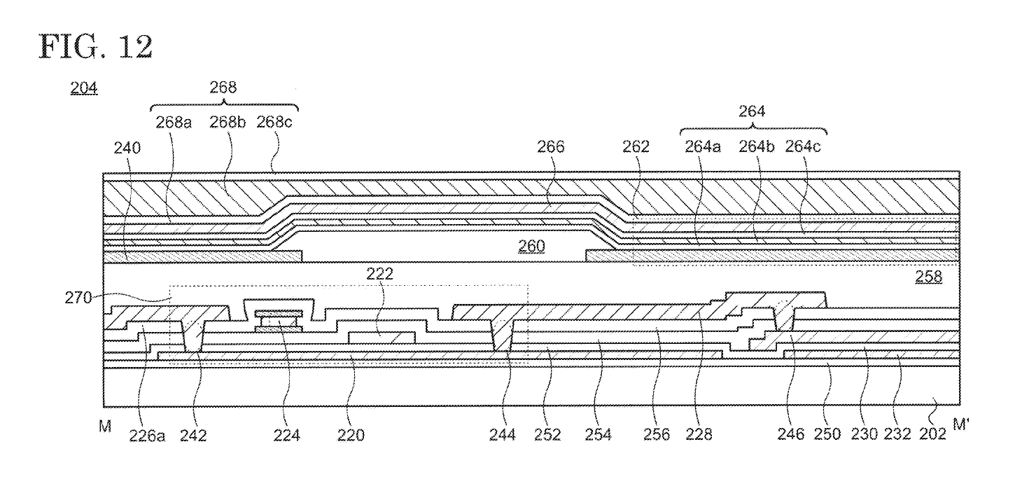

The schematic cross-sectional view along the chain line M-M′ is shown in FIG. 12. As demonstrated in FIG. 12, each element such as the switching transistor 270 and the light-emitting element 262 is disposed over the substrate 202 through an undercoat 250. The substrate 202 may include glass, quartz, or plastics. The use of a substrate having flexibility as the substrate 202 provides flexibility to the display device 200, by which a so-called flexible display can be manufactured.

The undercoat 250 may have a single-layer structure or may be composed of a plurality of films. The undercoat 250 includes a silicon-containing inorganic compound and typically includes silicon nitride and silicon oxide. When the undercoat 250 is formed with a plurality of films, a film including silicon oxide, a film including silicon nitride, and a film containing silicon oxide may be formed over the substrate 202 in this order, for example. The lowest film including silicon oxide is provided to improve adhesion with the substrate 202, the middle film including silicon nitride is provided as a blocking film preventing entrance of impurities such as water from outside, and the uppermost film including silicon oxide is provided as a blocking layer preventing hydrogen atoms in the film containing silicon nitride from being diffused to the side of the semiconductor film 220.

The semiconductor film 220 is formed over the undercoat 250, and the gate line 222 and the gate electrode 230 are arranged through a gate insulating film 252 so as to overlap with the semiconductor film 220. A region of the semiconductor film 220 overlapping with the gate line 222 is a channel region of the switching transistor 270, and impurity ions imparting conductivity are appropriately added to the regions sandwiching the channel region. In other words, a portion of the gate line 222 overlapping with the semiconductor film 222 functions as the gate of the switching transistor 270. The gate electrode 230 exists in the same layer as the gate line 222 and also functions as the gate 230b of the driving transistor 272 and the one terminal 230a of the storage capacitor 274 as described below. Similar to the undercoat 250, the gate insulating film 252 also includes a silicon-containing inorganic compound and is arranged so as to have a single-layer structure or a stacked-layer structure. The gate line 222 and the gate electrode 230 include the metal or the alloy thereof usable for the first wiring 102 and the second wiring 108 described in the First Embodiment. In addition, the gate line 222 and the gate electrode 230 may have a single-layer structure or the stacked-layer structure (the three-layer structure or the like) described in the First Embodiment. The semiconductor film 220 functions as the third wiring 134 of the wiring structure 140 and may have the same structure as that of the third wiring 134.

A first interlayer insulating film 254 is disposed so as to cover the gate line 222 and the gate electrode 230, over which the current-supplying line 224 and a second interlayer insulating film 256 covering the current-supplying line 224 are formed. The gate insulating film 252 and the first interlayer insulating film 254 collectively function as the third insulating film 112 of the wiring structure 140. On the other hand, the current-supplying line 224 functions as the first wiring 102 of the wiring structure 140 and is configured to supply current to the light-emitting element 262 through the driving transistor 272 as described below. Similar to the undercoat 250, the first interlayer insulating film 254 and the second interlayer insulating film 256 also include a silicon-containing inorganic compound and is formed to have a single-layer structure or a stacked-layer structure.

The pixel 204 further possesses, over the second interlayer insulating film 256, the signal line 226a and the drain electrode 228 existing in the same layer as each other. The drain electrode 228 is a second terminal of the switching transistor 270, and a part of the signal line 226a functions as the source electrode (first terminal) of the switching transistor 270. As described below, the signal line 226b of the pixel 204 adjacent to this pixel 204 functions as the second wiring 108 of the wiring structure 140.

The gate insulating film 252, the first interlayer insulating film 254, and the second interlayer insulating film 256 are respectively provided with openings 242, 244, and 246 reaching the semiconductor film 220 or the gate electrode 230. The signal line 226a and the drain electrode 228 are electrically connected to the semiconductor film 220 through the openings 242 and 244, respectively. On the other hand, the drain electrode 222 is further electrically connected to the gate electrode 230 through the opening 246. The switching transistor 270 is structured by the semiconductor film 220, the gate insulating film 252, the gate line 222, the first interlayer insulating film 254, the second interlayer insulating film 256, the signal line 226a, and the drain electrode 228.

A leveling film 258 is disposed over the switching transistor 270. The leveling film 258 includes a polymer such as an acrylic resin, an epoxy resin, a polyester, a polysiloxane, and a polyimide. The pixel electrode 240 is further formed over the leveling film 258, and a partition wall 260 is provided so as to cover an edge portion of the pixel electrode 240. Depressions and projections caused by the pixel electrode 240 are absorbed by the partition wall 260, thereby preventing disconnection of an electroluminescence layer (hereinafter, referred to as an EL layer) 264 and an opposing substrate 266 formed thereover. The partition wall 260 may also include the polymer described above.

The EL layer 264 and the opposing electrode 266 covering the EL layer 264 are formed so as to cover the pixel electrode 240 and the partition wall 260. The light-emitting element 262 is structured by the pixel electrode 240, the EL layer 264, and the opposing substrate 266.

The pixel electrode 240 is provided to inject holes to the EL layer 264, and a surface thereof is preferred to have a relatively high work function. When light-emission from the light-emitting element 262 is extracted through the pixel electrode 240, the pixel electrode 240 is configured to transmit visible light. In this case, a conductive oxide capable of transmitting visible light, such as indium-tin oxide (ITO) and indium-zinc oxide (IZO), is used as a specific material. On the other hand, when the light emission from the light-emitting element 262 is extracted through the opposing electrode 266, the pixel electrode 240 is configured to reflect visible light. In this case, the pixel electrode 240 includes a metal with high reflectance such as silver and aluminum. Alternatively, the pixel electrode 240 may have a stacked-layer structure of a film including a conductive oxide and a film including a metal with high reflectance. For example, a stacked-layer structure of a first conductive film including a conductive oxide, a second conductive film including a metal such as silver and aluminum, and a third conductive film including a conductive oxide may be employed.

The structure of the EL layer 264 may be arbitrarily selected, and the EL layer 264 may be formed by appropriately combining functional layers such as a hole-injection layer, a hole-transporting layer, an emission layer, an electron-transporting layer, an electron-injection layer, an electron-blocking layer, a hole-blocking layer, and an exciton-blocking layer. The structure of the EL layer 264 may be the same in all of the pixels 204, or part of the structure may be different between adjacent pixels 204. For example, the pixels 204 may be configured so that a structure or a material of the emission layer is different, but the other layers have the same structure between adjacent pixels 204. In FIG. 12, a hole-transporting layer 264a, an emission layer 264b, and an electron-transporting layer 264c are illustrated as typical functional layers for visibility.

When the light emission from the light-emitting element 262 is extracted through the pixel electrode 204, the opposing electrode 266 is configured to reflect visible light. Specifically, the opposing electrode 266 is formed by using a metal with high reflectance such as aluminum, silver, magnesium, or an alloy thereof (e.g., an alloy of magnesium and silver). On the other hand, when the light emission from the light-emitting element 262 is extracted though the opposing electrode 266, the opposing electrode 266 is configured to include a conductive oxide capable of transmitting visible light. Alternatively, the metal or alloy described above may be deposited at a thickness which allows visible light to pass therethrough. In this case, a film of a conductive oxide exhibiting a light-transmitting property with respect to visible light may be further formed.

As an optional structure, a passivation film 268 is arranged over the opposing substrate 266. The structure of the passivation film 268 may be also arbitrarily determined, and a single-layer structure or a stacked-structure may be employed. When the passivation film 268 has a stacked-layer structure, it is possible to employ, for example, the structure in which a first layer 268a including a silicon-containing inorganic compound, a second layer 268b including a resin, and a third layer 268c including a silicon-containing inorganic compound are stacked in this order as shown in FIG. 12. As a silicon-containing inorganic compound, silicon nitride and silicon oxide are represented. As a resin, an epoxy resin, an acrylic resin, a polyester, and a polycarbonate are represented.

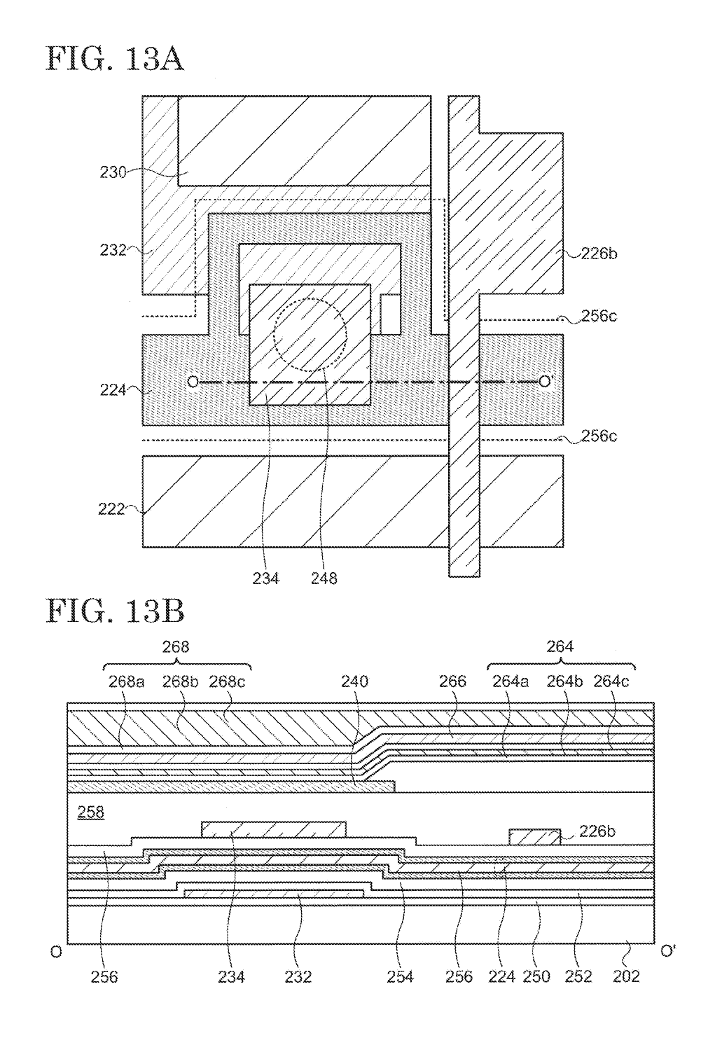

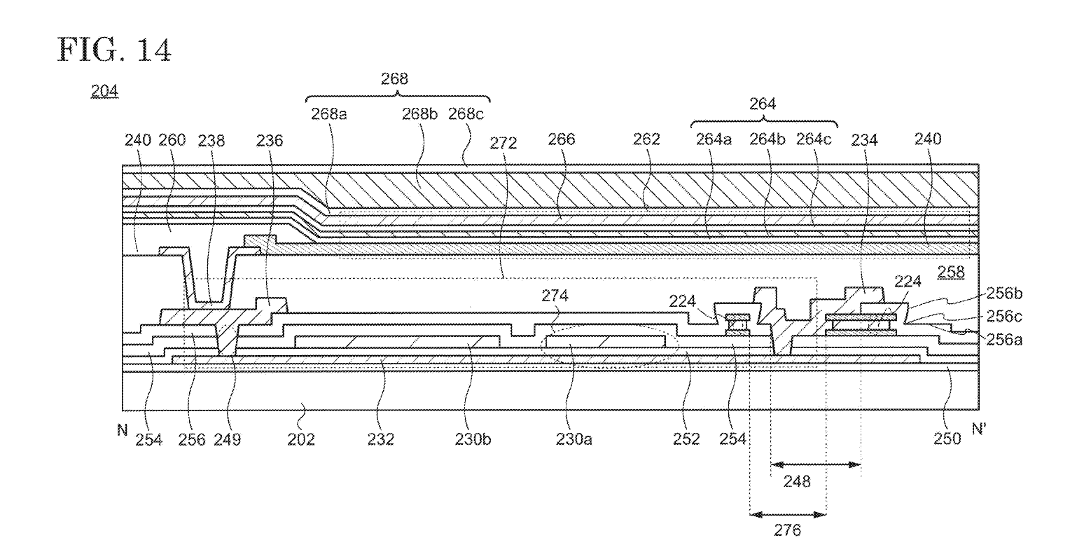

An enlarged top view of the source electrode 234 and a vicinity thereof is schematically illustrated in FIG. 13A. As shown in FIG. 13A, the wiring structure 140 is applied to the source electrode 234, the current-supplying line 224, and the semiconductor film 232 of one pixel 204 and the signal line 226b of the pixel 204 adjacent to this one pixel 204. These items respectively correspond to the electrode 106, the first wiring 102, the third wiring 134, and the second wiring 108 of the wiring structure 140. A more specific explanation is provided by using a schematic cross-sectional view (FIG. 14) along a chain line N-N′ of FIG. 11.

As shown in FIG. 14, the semiconductor film 232 is provided over the substrate 202 through the undercoat 250 in the pixel 204. The gate insulating film 252 is disposed over the semiconductor film 232 over which the gate electrode 230 is formed so as to overlap with the semiconductor film 232. A part of the gate electrode 230 functions as the one electrode 230a of the storage capacitor 274, and another part functions as the gate 230b of the driving transistor 272. A channel region is formed in the region of the semiconductor film 232 overlapping with the gate 230b. The regions sandwiching this channel region are appropriately doped with impurity ions. The storage capacitor 274 is structured by the electrode 230a as well as a part of the gate insulating film 252 and a part of the semiconductor film 232 overlapping with the electrode 230a.

Over the gate electrode 230, the first interlayer insulating film 254, the current-supplying line 224, and the second interlayer insulating film 256 overlapping with the current-supplying line 224 are disposed in this order. As demonstrated in FIG. 14, the current-supplying line 224 may have a three-layer structure. Although not illustrated, the source electrode 234 and the drain electrode 236 may also be structured with a plurality of stacked conductive films.

The drain electrode 236 (second terminal) and the source electrode 234 (first terminal) are arranged over the second interlayer insulating film 256. The gate insulating film 252, the first interlayer insulating film 254, and the second interlayer insulating film 256 are provided with an opening 249 through which the drain electrode 236 is electrically connected to the semiconductor film 232. In addition, an opening 276 is formed in the current-supplying line 224. The gate insulating film 252, the first interlayer insulating film 254, and the second interlayer insulating film 256 are each provided with an opening (hereinafter, the openings formed in the gate insulating film 252, the first interlayer insulating film 254, and the second interlayer insulating film 256 are collectively referred to as an opening 248) overlapping with the opening 276. The source electrode 234 is electrically connected to the current-supplying line 224 and the semiconductor film 232 through the openings 276 and 248. The driving transistor 272 is structured by the semiconductor film 232, the gate insulating film 252, the gate 230b, the first interlayer insulating film 254, the second interlayer insulating film 256, the source electrode 234, and the drain electrode 236. The leveling film 258 is disposed so as to cover the driving transistor 272.

Here, the gate insulating film 252 and the first interlayer insulating film 254 collectively function as the third insulating film 112 of the wiring structure 140, while the second interlayer insulating film 256 functions as the first insulating film 104. Moreover, the leveling film 258 functions as the second insulating film 110, and the openings 276 and 248 correspond to the openings 144 and 142, respectively. Thus, the second interlayer insulating film 256 is in contact with the first interlayer insulating film 254 and the leveling film 258 in the opening 276.

The leveling film 258 is provided with an opening reaching the drain electrode 236, and the connection electrode 238 is formed so as to cover this opening and a part of the leveling film 258. The connection electrode 238 may include ITO or IZO. The formation of the connection electrode 238 prevents corrosion of a surface of the drain electrode 236 in the following processes, thereby suppressing an increase in contact resistance between the drain electrode 236 and the pixel electrode 240. The pixel electrode 240 is formed over the leveling film 258 and electrically connected to the connection electrode 238. With this structure, the current supplied from the current-supplying line 224 is provided to the pixel electrode 240 through the driving transistor 272.

As the structures arranged over the pixel electrode 240 are the same as those of FIG. 12, an explanation is omitted.

In one pixel 204, the gate insulating film 252 and the first interlayer insulating film 254 collectively function as the third insulating film 112 of the wiring structure 140, the current-supplying line 224 functions as the first wiring 102 of the wiring structure 140, the second interlayer insulating film 256, the leveling film 258, and the source electrode 234 respectively function as the first insulating film 104, the second insulating film 110, and the electrode 106 of the wiring structure 140 as described above. In addition, the signal line 206b of the pixel 204 adjacent to the one pixel 204 functions as the second wiring 108 of the wiring structure 140. The opening 276 is formed in the current-supplying line 224, which causes the current-supplying line 224 to have the bypass structure surrounding a part of the source electrode 234 (see FIG. 13A). Therefore, a step is produced in the second interlayer insulating film due to the three-layer structure of the current-supplying line 224 as described in the First Embodiment. Moreover, in the case where a reverse-taper shape is generated in the step due to the three-layer structure, an etching residue formed when the source electrode 234 and the drain electrode 236 are prepared is likely to remain at the boundary 256c between a side surface 256b forming the step and a top surface 256a which is in contact with the side surface 256b and does not overlap with the current-supplying line 224 (see FIG. 14). This boundary 256c is formed along the bypass structure of the current-supplying line 224 as indicated by a dotted line in FIG. 13A. Therefore, the boundary 256c overlaps with the signal line 226b of the pixel 204 adjacent to the one pixel 204 but does not overlap with the source electrode 234 of the one pixel 204. Therefore, it is possible to prevent a short circuit between the source electrode 204 of the one pixel 204 and the signal line 226b of the adjacent pixel 204. This effect is particularly effective in the case where an increase in resolution of a display device requires reduction of a distance between the adjacent pixels. For instance, implementation of the wiring structure 140 is particularly effective in the case where, between the source electrode 234 of the one pixel 204 and the signal line 226b of the adjacent pixel 204, no wiring nor electrode existing in the same layer as the source electrode 234 of the one pixel 204 and the signal line 226b of the adjacent pixel 204 is provided and a top surface of the second interlayer insulating film 256 is entirely in contact with the leveling film 258 as demonstrated in a schematic cross-sectional view (FIG. 13B) along a chain line O-O′ in FIG. 13A. Hence, application of the wiring structure of the embodiment of the present invention enables production of a highly reliable display device capable of high-resolution display.

### 3. Modified Example 1

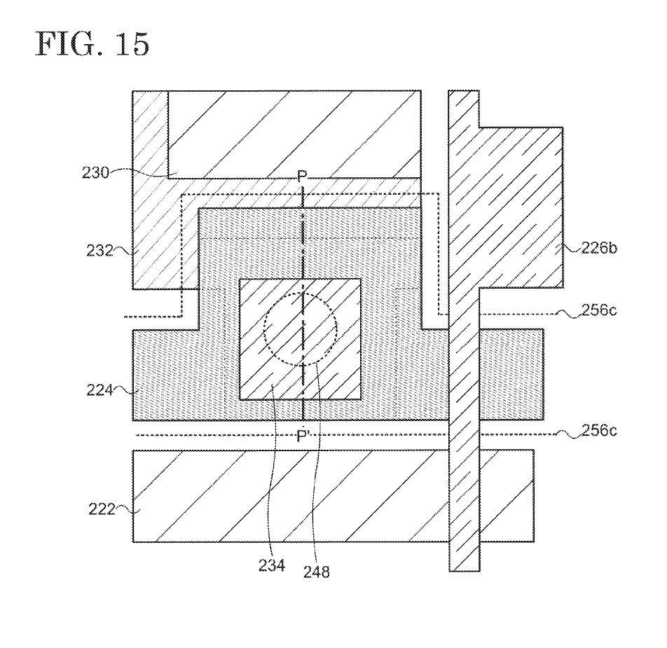

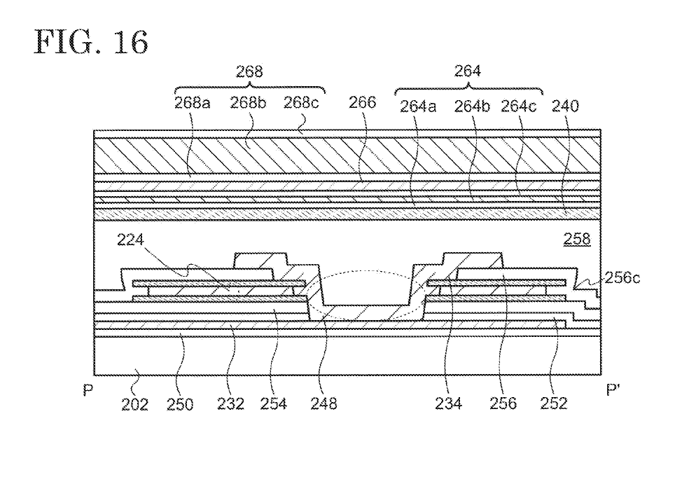

It is possible to apply other wiring structures 100, 120, and 130 to the display device 200. An enlarged top view of the source electrode 234 and a vicinity thereof in the case where the wiring structure 130 (see FIG. 7A to FIG. 7C) is applied is shown in FIG. 15, and a schematic cross-sectional view along a chain line P-P′ in FIG. 15 is shown in FIG. 16. As demonstrated in FIG. 15, the entire source electrode 234 overlaps with an outline of the current-supplying line 224.

As demonstrated in FIG. 16, the gate electrode 252, the first interlayer insulating film 254, the current-supplying line 224, and the second interlayer insulating film 256 are each provided with an opening (hereinafter, these openings are collectively referred to as an opening 248), and the source electrode 234 is electrically connected to the current-supplying line 224 and the semiconductor film 232 through the opening 248. Sidewalls of the openings of the gate insulating film 252, the first interlayer insulating film 254, and the current-supplying line 224 may exist in substantially the same plane. The sidewall of the opening of the second interlayer insulating film 256 may overlap with a top surface of the current-supplying line 224.

The semiconductor film 232, the current-supplying line 224, the second interlayer insulating film 256, the source electrode 234, and the leveling film 258 in one pixel 204 respectively correspond to the third wiring 134, the first wiring 102, the first insulating film 104, the electrode 106, and the second insulating film 110 of the wiring structure 130, and the gate insulating film 252 and the first interlayer insulating film 254 in the one pixel collectively correspond to the third insulating film 112 of the wiring structure 130. In addition, the signal line 226b of the pixel 204 adjacent to the one pixel 204 corresponds to the second wiring 108 of the wiring structure 130. As shown in FIG. 16, when the current-supplying line 224 has the three-layer structure including the first conductive film 224a, the second conductive film 224b, and the third conductive film 224c and a side surface of the second conductive film 224b overlaps with a top surface of the first conductive film 224a or a bottom surface of the third conductive film 224c, a step having a reverse-taper shape in the second interlayer insulating film 256 is produced due to the current-supplying line 224. When the reverse-taper shape is formed, an etching residue formed during the preparation of the source electrode 234 and the drain electrode 236 is likely to remain at the boundary 256c.

Similar to the display device 200 to which the wiring structure 140 is applied, although this boundary 256c overlaps with the signal line 226b of the pixel 204 adjacent to the one pixel 204, the boundary 256c does not overlap with the source electrode 234 in the one pixel 204 because the boundary 246c is formed along the outline of the current-supplying line 224 as indicated by a dotted line in FIG. 15. Hence, it is possible to prevent a short circuit between the source electrode 234 in the one pixel and the signal line 226b in the pixel 204 adjacent to the one pixel 204. Accordingly, implementation of the present invention enables production of a highly reliable display device capable of high-resolution display.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A wiring structure comprising:
a first wiring;
a first insulating film over the first wiring;
a second wiring over the first insulating film and intersecting the first wiring;
an electrode over the first insulating film and spaced from the second wiring; and
a second insulating film over the second wiring and the electrode,
wherein an entire region of the electrode overlaps with the first wiring in a plan view, and
a top surface of the first insulating film is entirely in contact with the second insulating film in a region immediately over the first wiring and between the second wiring and the electrode.

2. The wiring structure according to claim 1,
wherein the first wiring comprises:
a first conductive film;
a second conductive film over the first conductive film; and
a third conductive film over the second conductive film,
the first conductive film and the third conductive film each include titanium, molybdenum, tungsten, or tantalum, and
the second conductive film includes aluminum or copper.

3. The wiring structure according to claim 2,
wherein a side surface of the second conductive film overlaps with at least one of a top surface of the first conductive film and a bottom surface of the third conductive film.

4. The wiring structure according to claim 1,
wherein the first insulating film has a step caused by the first wiring, and
an angle between a top surface of the first insulating film, which does not overlap with the first wiring, and a side surface of the first insulating film in the step is equal to or more than 0° and equal to or less than 90°.

5. The wiring structure according to claim 1,
wherein the first insulating film has an opening overlapping with the first wiring, and
the electrode is electrically connected to the first wiring through the opening.

6. The wiring structure according to claim 1, further comprising:
a third wiring under the first wiring; and
a third insulating film between the first wiring and the third wiring,
wherein the first wiring, the first insulating film, and the third insulating film each have an opening, and
the electrode is electrically connected to the first wiring and the third wiring through the openings of the first wiring, the first insulating film, and the third insulating film.

7. The wiring structure according to claim 6,
wherein the first insulating film and the third insulating film are in contact with each other in the opening of the first wiring.

8. The wiring structure according to claim 6,
wherein the third wiring includes silicon.

9. A display device comprising:
a transistor including a semiconductor film, a gate insulating film over the semiconductor film, a gate over the gate insulating film, a first interlayer insulating film over the gate, a second interlayer insulating film over the first interlayer insulating film, a first terminal over the second interlayer insulating film, and a second terminal over the second interlayer insulating film;
a leveling film over the transistor;
a display element over the leveling film and electrically connected to the second terminal; and
a first wiring sandwiched between the first interlayer insulating film and the second interlayer insulating film and electrically connected to the first terminal,
wherein the first wiring has a first opening, and the second interlayer insulating film is in contact with the leveling film and the first interlayer insulating film through the first opening.

10. The display device according to claim 9,
wherein the gate insulating film, the first interlayer insulating film, and the second interlayer insulating film each have a second opening overlapping with the first opening of the first wiring, and
wherein the first terminal is electrically connected to the semiconductor film through the second openings of the first wiring, the gate insulating film, the first interlayer insulating film, and the second interlayer insulating film.

11. The display device according to claim 9,
wherein the first wiring comprises:
a first conductive film;
a second conductive film over the first conductive film; and
a third conductive film over the second conductive film,
the first conductive film and the third conductive film each include titanium, molybdenum, tungsten, or tantalum, and
the second conductive film includes aluminum or copper.

12. The display device according to claim 11,
wherein a side surface of the second conductive film overlaps with at least one of a top surface of the first conductive film and a bottom surface of the third conductive film.

13. The display device according to claim 9,
wherein the second interlayer insulating film has a step caused by the first wiring, and
an angle between a top surface of the second interlayer insulating film, which does not overlap with the first wiring, and a side surface of the second interlayer insulating film in the step is equal to or more than 0° and equal to or less than 90°.

14. The display device according to claim 9
wherein the display element is an electroluminescence element, and
the first wiring is configured to supply current to the display element.

15. A display device comprising:
a transistor including a semiconductor film, a gate insulating film over the semiconductor film, a gate over the gate insulating film, a first interlayer insulating film over the gate, a second interlayer insulating film over the first interlayer insulating film, a first terminal over the second interlayer insulating film, and a second terminal over the second interlayer insulating film;
a display element electrically connected to the second terminal; and
a first wiring sandwiched between the first interlayer insulating film and the second interlayer insulating film and electrically connected to the first terminal,
wherein the entire first terminal is surrounded by an outline of the first wiring.

16. The display device according to claim 15,
wherein the first wiring, the gate insulating film, the first interlayer insulating film, and the second interlayer insulating film each have an opening, and
the first terminal is electrically connected to the semiconductor film through the openings.

17. The display device according to claim 15,
wherein the first wiring comprises:
a first conductive film;
a second conductive film over the first conductive film; and
a third conductive film over the second conductive film,
the first conductive film and the third conductive film each include titanium, molybdenum, tungsten, or tantalum, and
the second conductive film include aluminum or copper.

18. The display device according to claim 17,
wherein a side surface of the second conductive film overlaps with at least one of a top surface of the first conductive film and a bottom surface of the third conductive film.

19. The display device according to claim 15,
wherein the second insulating film has a step caused by the first wiring, and
an angle between a top surface of the second interlayer insulating film, which does not overlap with the first wiring, and a side surface of the second interlayer insulating film in the step is equal to or more than 0° and equal to or less than 90°.

20. The display device according to claim 15,
wherein the display element is an electroluminescence element, and
the first wiring is configured to supply current to the display element.
